(19) United States
(12) Patent Application Publication
(10) Pub. No.: US 2025/0183100 A1
(43) Pub. Date: Jun. 5, 2025

(54) METHOD FOR DETERMINING HEALTH INDEX OF SUBSTRATE PROCESSING APPARATUS AND SUBSTRATE PROCESSING APPARATUS

(71) Applicant: EBARA CORPORATION, Tokyo (JP)

(72) Inventors: Shaunak GHATPANDE, Tokyo (JP); Rohit KAWDE, Tokyo (JP); Ryuya KOIZUMI, Tokyo (JP); Tensei SATO, Tokyo (JP); Shunsuke KAGAYA, Tokyo (JP)

(21) Appl. No.: 18/959,266

(22) Filed: Nov. 25, 2024

(30) Foreign Application Priority Data
Dec. 1, 2023 (JP) 2023-203847

(51) Int. Cl. H01L 21/66

(52) U.S. Cl. CPC H01L 22/10

(57) ABSTRACT

In a substrate processing apparatus comprising multiple modules, the state of health of the whole substrate processing apparatus is grasped. A method for determining a health index of a substrate processing apparatus is provided. The substrate processing apparatus comprises multiple module groups, and each module group comprises a single module or multiple modules. The method comprises steps for obtaining multiple operation parameter values relating to each of the modules in the substrate processing apparatus; determining a module state of each of the modules, based on the multiple operation parameter values; and determining a health index of the substrate processing apparatus, based on the module states of the modules and weight coefficients for the modules.

### TECHNICAL FIELD

The present invention relates to a method for determining a health index of a substrate processing apparatus, and a substrate processing apparatus.

### BACKGROUND ART

A method for calculating, with respect to each motor in a transfer unit installed in a substrate processing apparatus, the degree of health has been known (for example, refer to Patent Literature 1 (Claim 1 thereof)).

### CITATION LIST

### Patent Literature

PTL 1: Japanese Patent Publication No. 7233201

### SUMMARY OF INVENTION

### Technical Problem

With respect to a substrate processing apparatus which comprises multiple modules, it is desired to grasp the state of health of the whole substrate processing apparatus. By grasping the state of health of the whole substrate processing apparatus, it becomes possible to prevent lengthening of downtime of the substrate processing apparatus, for example.

### Solution to Problem

(Mode 1) According to mode 1, a method for determining a health index of a substrate processing apparatus is provided; wherein the substrate processing apparatus comprises multiple module groups, and each module group comprises a single module or multiple modules; and the method comprises steps for obtaining multiple operation parameter values relating to each of the modules in the substrate processing apparatus; determining a module state of each of the modules, based on the multiple operation parameter values; and determining a health index of the substrate processing apparatus, based on the module states of the modules and weight coefficients for the modules.

(Mode 2) According to mode 2, the mode 2 comprises the method of the mode 1, wherein the weight coefficient for each of the modules comprises a first weight coefficient that represents a first kind of contribution by the module to the health index and a second weight coefficient that represents a second kind of contribution by the module to the health index.

(Mode 3) According to mode 3, the mode 3 comprises the method of the mode 2, wherein: the substrate processing apparatus is constructed to apply, to a substrate, a series of processes by performing characteristic functional actions by the module groups, respectively; the first weight coefficients are set to values corresponding to the degrees of importance of the functional actions, in the series of processes, performed by the module groups, respectively; and the second weight coefficients are set to values corresponding to the numbers of useable modules included in the module groups, respectively.

(Mode 4) According to mode 4, the mode 4 comprises the method of the mode 3, and the method further comprises steps for: controlling use or nonuse of each of the modules, based on the module state of the module; and changing, in the case that a module being used in the modules is made to be unused or a module being unused in the modules is made to be used, the second weight coefficient according to change in the number of usable modules.

(Mode 5) According to mode 5, the mode 5 comprises the method of any one of the modes 2-4, wherein the step for determining the health index comprises calculating, in relation to each module, a product of the module state value, the first weight coefficient, and the second weight coefficient.

(Mode 6) According to mode 6, the mode 6 comprises the method of the mode 5, wherein the step for determining the health index comprises calculating the sum of the products relating to all modules, wherein each of the products is that calculated in relation to each of the modules.

(Mode 7) According to mode 7, the mode 7 comprises the method of the mode 1, and the method further comprises a step for controlling use or nonuse of each module, based on the module state of the module.

(Mode 8) According to mode 8, the mode 8 comprises the method of the mode 7, and the method further comprises a step for performing discretization of the multiple operation parameter values relating to each module, based on predetermined threshold values, respectively; wherein the step for determining the module state comprises calculating the sum of the discretized multiple operation parameter values relating to the module, or the sum of the multiple operation parameter values relating to the module.

(Mode 9) According to mode 9, the mode 9 comprises the method of the mode 7 or 8, and the method further comprises a step for identifying an abnormal operation parameter, with respect to a module which has been controlled to be unused in the modules, based on the multiple operation parameter values or the discretized multiple operation parameters.

(Mode 10) According to mode 10, a method for determining a health index of a substrate processing apparatus is provided; wherein the substrate processing apparatus comprises multiple module groups, and each module group comprises a single module or multiple modules; and the method comprises steps for obtaining multiple operation parameter values relating to each of the modules in the substrate processing apparatus; training a learning model by machine learning, for making it output a value relating to a health index of the substrate processing apparatus when the multiple operation parameter values relating to multiple modules in the substrate processing apparatus are inputted thereto; and inferring, by using the trained learning model and from multiple operation parameter values of the multiple modules at present, a health index of the substrate processing apparatus at present: wherein the step for training the learning model by machine learning comprises steps for calculating a module state of each module, by calculating, with respect to the module, the sum of the multiple operation parameter values or discretized values of the multiple operation parameter values; calculating a health index of the substrate processing apparatus, by calculating the sum of products, each product being a product of a module state of each module and a weight coefficient for the module; and training the learning model by using, as training data, the multiple operation parameter values relating to the multiple modules in the substrate processing apparatus and the calculated health index.

(Mode 11) According to mode 11, the mode 11 comprises the method of the mode 10, wherein the trained learning model is installed in the substrate processing apparatus.

(Mode 12) According to mode 12, a substrate processing apparatus comprising a controller and multiple module groups is provided; wherein each module group comprises a single module or multiple modules; and the controller is constructed to obtain multiple operation parameter values relating to each of the modules in the substrate processing apparatus; determine a module state of each of the modules, based on the multiple operation parameter values; and determine a health index of the substrate processing apparatus, based on the module states of the modules and weight coefficients for the modules.

(Mode 13) According to mode 13, a substrate processing apparatus comprising a controller and multiple module groups is provided; wherein each module group comprises a single module or multiple modules; and the controller is constructed to obtain multiple operation parameter values relating to each of the modules in the substrate processing apparatus; and infer, by using a learning model trained by machine learning for outputting a value relating to a health index of the substrate processing apparatus when the multiple operation parameter values relating to multiple modules in the substrate processing apparatus are inputted thereto, and from multiple operation parameter values of the multiple modules at present, a health index of the substrate processing apparatus at present: wherein the learning model is that trained by calculating a module state of each module, by calculating, with respect to the module, the sum of the multiple operation parameter values or discretized values of the multiple operation parameter values; calculating a health index of the substrate processing apparatus, by calculating the sum of products, each product being a product of a module state of each module and a weight coefficient for the module; and training the learning model by using, as training data, the multiple operation parameter values relating to the multiple modules in the substrate processing apparatus and the calculated health index.

(Mode 14) According to mode 14, the mode 14 comprises the substrate processing apparatus of the mode 13, wherein the trained learning model is installed in the substrate processing apparatus.

### BRIEF DESCRIPTION OF DRAWINGS

FIG. 1 is a general configuration diagram of a plating apparatus according to an embodiment of the present invention.

FIG. 2 is a schematic diagram used for explaining a “module” and a “module group” in a plating apparatus according to a present embodiment.

FIG. 3 is a configuration diagram of an example system for implementing a method according to an embodiment of the present invention.

FIG. 4 is a flow chart which shows operation of a system for implementing a method according to an embodiment of the present invention.

FIG. 5 is a figure which shows operation parameters of each module.

FIG. 6 is a figure used for explaining an example of discretization.

FIG. 7 is a figure which shows calculation examples of module states.

FIG. 8 is a figure which shows examples of first weight coefficients.

FIG. 9 is a figure which shows examples of second weight coefficients.

FIG. 10 is a figure which shows, with respect to each module in a plating apparatus, examples of a module state and weight coefficients.

FIG. 11 is a figure which shows, with respect to each module in a plating apparatus, an example of result of judgment in terms of use/nonuse.

FIG. 12 is a figure which shows an example of a monitor screen.

FIG. 13 is a flow chart which shows operation of a system for implementing a method according to a different embodiment of the present invention.

FIG. 14 is a flow chart which shows operation of a system for implementing a method according to a different embodiment of the present invention.

FIG. 15A is a figure which shows an example of training data.

FIG. 15B is a figure which shows an example of training data.

FIG. 16 is a figure which shows a construction of an example learning model which can be used when implementing a method according to a present embodiment.

### DESCRIPTION OF EMBODIMENTS

In the following description, embodiments of the present invention will be explained with reference to the figures. In the figures which will be explained below, a reference symbol that is the same as that assigned to one component is assigned to the other component which is the same as or corresponds to the one component, and overlapping explanation of these components will be omitted.

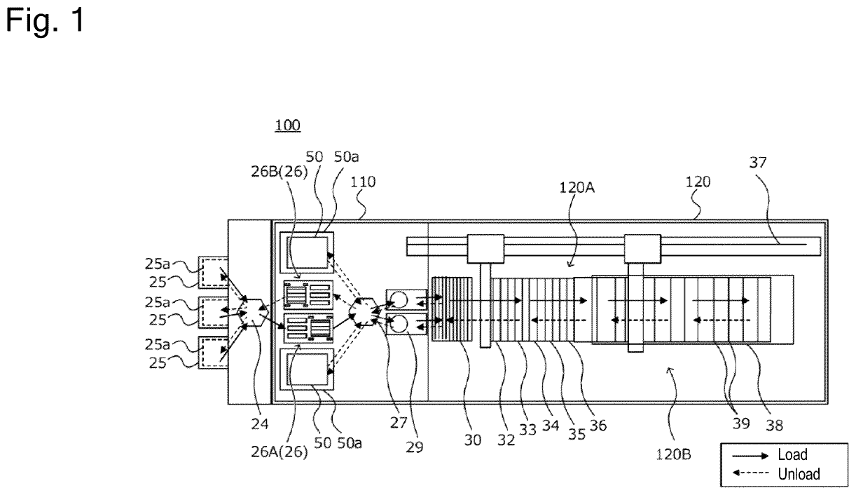

FIG. 1 is a general configuration diagram of a plating apparatus 100 according to an embodiment of the present invention. The plating apparatus 100 is an example of a substrate processing apparatus. In the following description, embodiments of the present invention will be explained with reference to the plating apparatus 100; however, the devices and the methods disclosed in the present specification are applicable to any of substrate processing apparatuses, in addition to a plating apparatus. For example, the substrate processing apparatuses comprise, in addition to a plating apparatus, any devices which process or treat substrates (for example, a semiconductor substrate, a glass substrate, a printed circuit board, and so on) by performing appropriately selected methods, such as a polishing device for polishing a substrate or a thin film formed on a substrate (for example, a CMP (Chemical Mechanical Polishing) device and so on), a film forming device for forming a film on a substrate (for example a CVD (Chemical Vapor Deposition) device, a vapor deposition device, and so on), an exposure device for transferring a fine pattern on a thin film on a substrate, an etching device for performing etching for finely processing a substrate or a thin film formed on a substrate, an ion implanting device for implanting ions in a substrate or a thin film formed on a substrate, a dicing device for cutting a substrate to form chips, various kinds of inspection devices (or measurement devices) for inspecting substrates or thin films formed on substrates, and so on.

When a reference is made to FIG. 1, the plating apparatus 100 comprises a load/unload unit 110 for loading a substrate on a substrate holder (which is not shown in the figure) and unloading a substrate from a substrate holder, and a processing unit 120 for processing a substrate. The processing unit 120 further comprises a pre-processing/post-processing unit 120A for performing pre-processing and post-processing of a substrate, and a plating processing unit 120B for applying a plating process to a substrate.

The load/unload unit 110 comprises a handling stage 26, a substrate transfer device 27, a fixing station 29, and a washing unit 50a. For example, in the present embodiment, the load/unload unit 110 comprises two handling stages 26, specifically, a handling stage 26A for loading, which handles a substrate to which no process has been applied, and a handling stage 26B for unloading, which handles a substrate to which a process has been applied thereto. In the present embodiment, the construction of the handling stage 26A for loading is the same as that of the handling stage 26B for unloading, and they are arranged in such a manner that the directions thereof are 180-degree opposite from each other. In this regard, the handling stage 26 is not limited to that comprising the handling stage 26A for loading and the handling stage 26B for unloading, and the handling stages may be used without discrimination, i.e., without setting one of them to be a handling stage for loading and the other of them to be a handling stage for unloading. Further, in the present embodiment, the load/unload unit 110 comprises two fixing stations 29. The mechanisms of the two fixing stations 29 are identical with each other; and one, that is free (i.e., that is not handling a substrate), of them is used. In this regard, one or three or more handling stage/stages 26 and one or three or more fixing station/stations 29 may be installed according to the space in the plating apparatus 100.

Substrates are conveyed from multiple cassette tables 25 (for example, three in FIG. 1) to the handling stage 26 (the handling stage 26A for loading) via a robot 24. The cassette table 25 is provided with a cassette 25a in which a substrate is stored. For example, the cassette is a FOUP. The handling stage 26 is constructed in such manner that it adjusts (aligns) the position and the direction of a substrate put thereon. A substrate transfer device 27 is arranged in a position between the handling stage 26 and the fixing station 29 for conveying a substrate between them. The substrate transfer device 27 is constructed to convey a substrate between the handling stage 26, the fixing station 29, and the washing unit 50a. Further, a stocker 30, which is used for storing substrate holders, is installed in a position near the fixing station 29.

The washing unit 50a comprises a spin rinse dryer 50 for cleaning a substrate, after completion of a plating process applied thereto, and drying the substrate by rotating it at high speed. The substrate transfer device 27 is constructed to convey a substrate, with respect to which a plating process applied thereto has been completed, to the spin rinse dryer 50, and take the washed and dried substrate out of the spin rinse dryer 50. Thereafter, the washed and dried substrate is delivered to the handling stage 26 (the handling stage 26B for unloading) by the substrate transfer device 27, and returned to the cassette 25a via the robot 24.

The pre-processing/post-processing unit 120A comprises a pre-wet tank 32, a pre-soak tank 33, a pre-rinse tank 34, a blow tank 35, and a rinse tank 36. In the pre-wet tank 32, a substrate is soaked into pure water. In the pre-soak tank 33, an oxide film on a surface of a conductive layer, such as a seed layer or the like, formed on a surface of a substrate is removed by etching. In the pre-rinse tank 34, a substrate, with respect to which a pre-soaking process applied thereto has been completed, is washed together with a substrate holder by using cleaning liquid (pure water or the like). In the blow tank 35, liquid removal of a washed substrate is performed. In the rinse tank 36, a plated substrate is washed together with a substrate holder by using cleaning liquid. In this regard, the construction of the pre-processing/post-processing unit 120A is a mere example, and, accordingly, the construction of the pre-processing/post-processing unit 120A in the plating apparatus 100 is not limited to the above construction, and a different construction may be adopted in place thereof.

The plating processing unit 120B is constructed, for example, in such a manner that multiple plating tanks 39 are housed in the inside of an overflow tank 38. Each plating tank 39 is constructed in such a manner that it stores a single substrate therein, and soaks the substrate into plating liquid held in the inside thereof and applies plating such as copper plating or the like to a surface of the substrate.

The plating apparatus 100 comprises a transporter 37 which adopts, for example, a linear motor system, and is arranged in a position on a side of the pre-processing/post-processing unit 120A and the plating processing unit 120B, for conveying a substrate holder together with a substrate. The transporter 37 is constructed to convey a substrate holder between the fixing station 29, the stocker 30, the pre-wet tank 32, the pre-soak tank 33, the pre-rinse tank 34, the blow tank 35, the rinse tank 36, and the plating tank 39.

An example of a series of plating processes performed by the plating apparatus 100 will be explained. First, by the robot 24, a single substrate is taken out of the cassette 25a loaded in the cassette table 25; and the substrate is conveyed to the handling stage 26 (the handling stage 26A for loading). The handling stage 26 aligns the position and the direction of the conveyed substrate with a predetermined position and a predetermined direction. The substrate, with respect to which the position and the direction have been aligned in the handling stage 26, is conveyed to the fixing station 29 by the substrate transfer device 27.

On the other hand, a substrate holder stored in the stocker 30 is conveyed to the fixing station 29 by the transporter 37, and put horizontally on the fixing station 29. Thereafter, the substrate conveyed by the substrate transfer device 27 is put on the substrate holder which is in the above state, and the substrate and the substrate holder are coupled with each other.

Next, the substrate holder, which holds the substrate, is grasped by the transporter 37, and stored in the pre-wet tank 32. Next, the substrate holder, which holds the substrate with respect to which the process applied thereto in the pre-wet tank 32 has been completed, is conveyed to the pre-soak tank 33 by the transporter 37, and an oxide film on the substrate is etched in the pre-soak tank 33. Following thereto, the substrate holder, which holds the above substrate, is conveyed to the pre-rinse tank 34 to water-wash the surface of the substrate by pure water stored in the pre-rinse tank 34.

The substrate holder, which holds the substrate with respect to which the water-washing process applied thereto has been completed, is conveyed from the pre-rinse tank 34 to the plating processing unit 120B by the transporter 37 to store it in the plating tank 39 which is filled with plating liquid. The transporter 37 repeats the above procedures sequentially to store respective substrate holders, which hold respective substrates, in respective plating tanks 39 in the processing unit 120 sequentially.

In each of the plating tanks 39, a surface of the substrate is plated by applying a plating voltage between an anode (which is not shown in the figure) in the plating tank 39 and the substrate.

After completion of plating, the substrate holder, which holds the plated substrate, is grasped by the transporter 37 and conveyed to the rinse tank 36 to soak it into pure water stored in the rinse tank 36 to wash the surface of the substrate by the pure water. Next, the substrate holder is conveyed to the blow tank 35 by the transporter 37 to remove water droplets remaining on the substrate holder by air-blowing or the like. Thereafter, the substrate holder is conveyed to the fixing station 29 by the transporter 37.

In the fixing station 29, the processed substrate is taken out of the substrate holder by the substrate transfer device 27, and conveyed to the spin rinse dryer 50 in the washing unit 50a. The spin rinse dryer 50 washes the substrate with respect to which the plating process applied thereto has been completed, and dries the substrate by rotating it at high speed. The dried substrate is delivered to the handling stage 26 (the handling stage 26B for unloading) by the substrate transfer device 27, and returned to the cassette 25a via the robot 24.

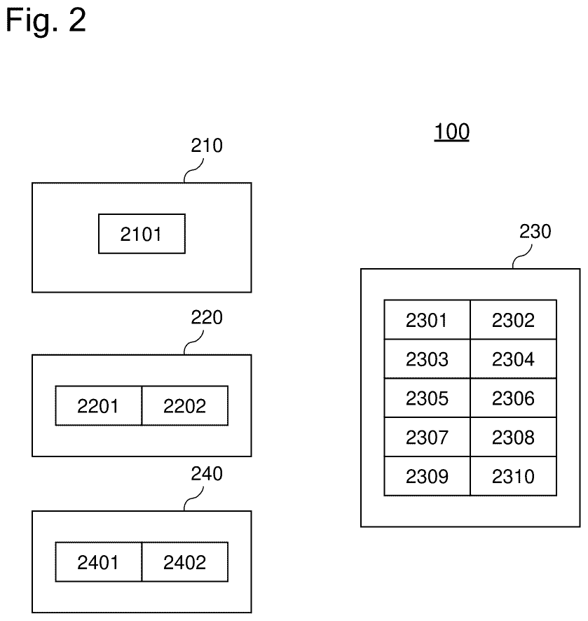

FIG. 2 is a schematic diagram used for explaining a “module” and a “module group” in the plating apparatus 100 according to the present embodiment. In the example in FIG. 2, the plating apparatus 100 comprises a first module group 210, a second module group 220, a third module group 230, and a fourth module group 240. Further, in the example in FIG. 2, the first module group 210 comprises a single first module 2101, the second module group 220 comprises two second modules 2201-2202, the third module group 230 comprises ten third modules 2301-2310, and the fourth module group 240 comprises two fourth modules 2401-2402. For example, the first module 2101 in the first module group 210 may be that corresponding to the fixing station 29 explained with reference to FIG. 1; each of the second modules 2201-2202 in the second module group 220 may be that corresponding to the pre-wet tank 32 explained with reference to FIG. 1; each of the third modules 2301-2310 in the third module group 230 may be that corresponding to the plating tank 39 explained with reference to FIG. 1; and each of the fourth module 2401-2402 in the fourth module group 240 may be that corresponding to the spin rinse dryer 50 explained with reference to FIG. 1. That is, the example in FIG. 2 shows that the plating apparatus 100 comprises the first module group 210 comprising a single fixing station 29 (the first module), the second module group 220 comprising two pre-wet tanks 32 (the second modules), the third module group 230 comprising ten plating tanks 39 (the third modules), and the fourth module group 240 comprising two spin rinse dryers 50 (the fourth modules).

It should be reminded that FIG. 2 is a figure which shows four module groups 210, 220, 230, and 240 only, for convenience of explanation. The number of module groups can be selected arbitrarily, and, accordingly, three or less than three module groups or five or more than five module groups may be included therein. For example, the pre-soak tank 33, the pre-rinse tank 34, the blow tank 35, the rinse tank 36, and/or a component(s) other than these components in the plating apparatus 100 in FIG. 1 may form additional module groups such as a fifth module group, a sixth module group, and so on, respectively.

As explained above, the plating apparatus 100 comprises multiple module groups, and each module group comprises one module or multiple modules. The number of modules included in each module group is not limited to that in the example in FIG. 2, and the number may be any number equal to or greater than 1. The module groups perform characteristic functional actions, respectively. For example, in the example in FIG. 2, the third module group 230 performs, by using respective plating tanks 39 (the third modules 2301-2310) included therein, a predetermined plating process applied to each substrate. Also, the second module group 220 performs, in the respective pre-wet tanks 32 (the second modules 2201-2202), a process to soak each substrate into pure water.

In the example in FIG. 2, the third module group 230 comprises ten plating tanks 39 (the third modules 2301-2310), each having a construction similar to those of others; and the same processes can be performed in the respective tanks to apply the processes to respective substrates. That is, the third module group 230 can process, in parallel and at the same time, at most ten substrates by using the ten modules 2301-2310 at the same time. Similarly, in the example in FIG. 2, the second module group 220 can apply the same processes to substrates in the two pre-wet tanks 32 (the second modules 2201-2202) having constructions similar to each other, respectively. Explanation similar to the above explanation also apply to the fourth module group 240.

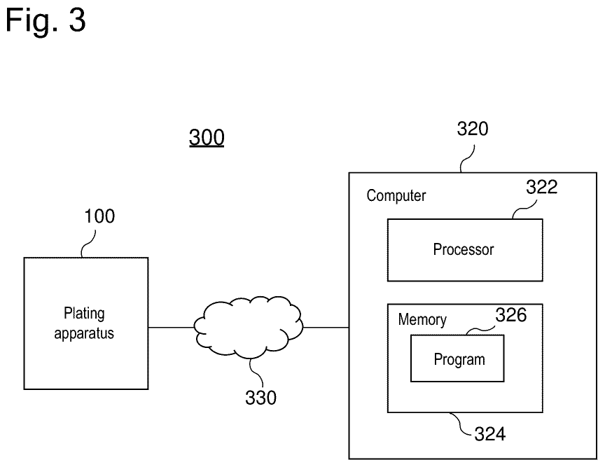

FIG. 3 is a configuration diagram of an example system 300 for implementing a method according to an embodiment of the present invention. The system 300 comprises a plating apparatus 100 and a computer 320. The plating apparatus 100 is the plating apparatus explained with reference to FIG. 1 or FIG. 2. The plating apparatus 100 and the computer 320 are connected with each other via a network 330, for example, a LAN (local area network), the Internet, or the like, to make them be able to communicate with each other. In a different construction, the computer 320 may be incorporated in the plating apparatus 100 as a part of the construction of the plating apparatus 100. The computer 320 comprises a processor 322 and a memory 324. A program 326 which is used for realizing the method according to an embodiment of the present invention is stored in the memory 324. The processor 322 reads the program 326 out of the memory 324 and executes it. As a result, it becomes possible to implement, by the system 300, the method according to the embodiment of the present invention. In this regard, it should be reminded that, although a single computer 320 only is shown in FIG. 3, the system 300 may comprise multiple computers 320. In such a construction, memories 324 in the computers 320 may store programs corresponding to parts of the method according to the embodiment of the present invention, respectively; and the processors 322 in the computers 320 may execute the programs, respectively, in such a manner that multiple computers 320 cooperate with one another to implement, as a whole, the method according to the embodiment of the present invention.

### First Embodiment

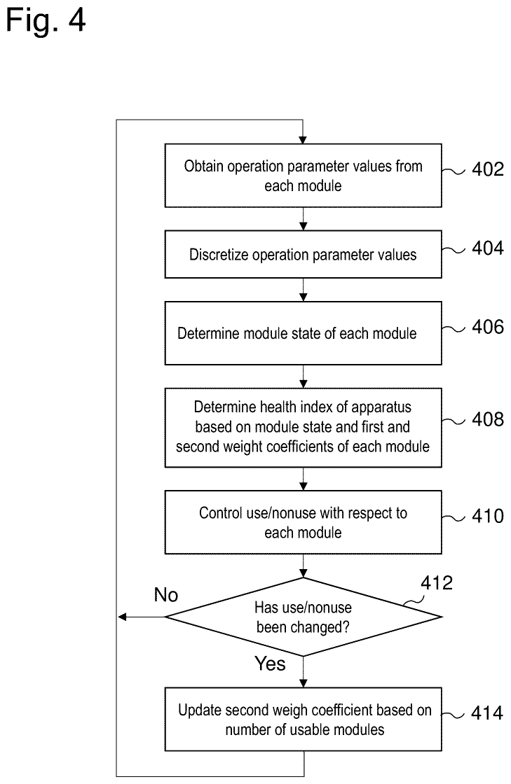

FIG. 4 is a flow chart which shows operation of the system 300 for implementing a method according to an embodiment of the present invention. The process in each step in the flow chart in FIG. 4 is performed by the processor 322 in the computer 320 in the system 300. The method according to the embodiment relating to FIG. 4 starts from step 402, during normal operation of the plating apparatus 100.

First, in step 402, the processor 322 obtains, from each module in the plating apparatus 100 (for example, each of the first module 2101, the second modules 2201-2202, the third modules 2301-2310, and the fourth modules 2401-2402 shown in FIG. 2), multiple operation parameter values. For example, in each module in the plating apparatus 100, values of various operation parameters are measured by various kinds of sensors at predetermined time intervals; and the operation parameter values are supplied sequentially from each module to the computer 320 in the system 300. The operation parameter values may be numerical values of any kinds of parameters relating to the operation/running state of the module.

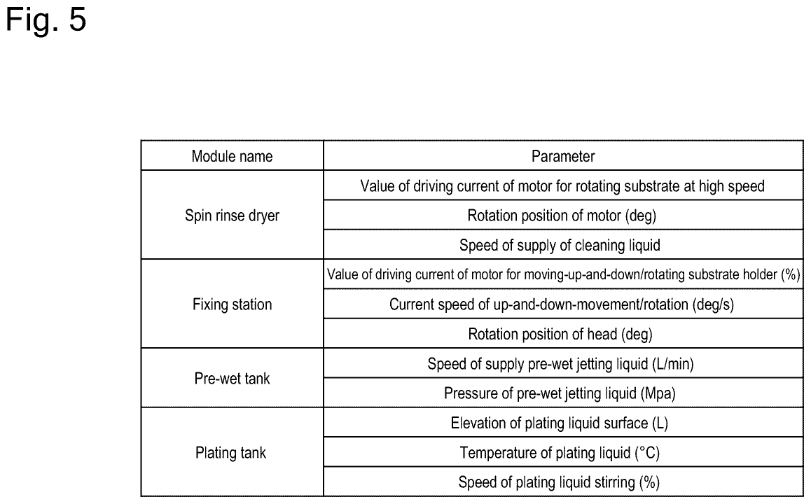

FIG. 5 shows examples of operation parameters of each module. When a reference is made to FIG. 5, for example, operation parameter values supplied from each of the fourth modules 2401-2402 (the spin rinse dryers 50) include the value of driving current of a motor for rotating a substrate at high speed, the rotation position (the angle) of the motor, and the speed of supply of cleaning liquid (pure water); operation parameter values supplied from the first module 2101 (the fixing station 29) include the value of driving current of a motor for moving-up-and-down/rotating a substrate holder, the current speed of up-and-down-movement/rotation, and the rotation position (the angle) of a head; operation parameter values supplied from each of the second modules 2201-2202 (the pre-wet tanks 32) include the speed of supply of pre-wet jetting liquid and the pressure of the pre-wet jetting liquid; and operation parameter values supplied from each of the third modules 2301-2310 (the plating tanks 39) include the elevation of the plating liquid surface, the temperature of the plating liquid, and the speed of plating liquid stirring. It should be reminded that the above operation parameters are mere examples, and the kinds of operation parameters and the number of operation parameters can be selected arbitrarily.

Next, in step S404, the processor 322 performs, based on respective predetermined threshold values, discretization of respective operation parameter values obtained in step 402. For example, the processor 322 may perform discretization by converting an obtained operation parameter value to a first value (for example, “1”) if the operation parameter value is that in a first numerical value range, converting an obtained operation parameter value to a second value (for example, “2”) if the operation parameter value is that in a second numerical value range, and converting an obtained operation parameter value to a third value (for example, “3”) if the operation parameter value is that in a third numerical value range. The upper limit and the lower limit of each numerical value range, the value that is to be assigned as a result of each conversion process, and the number of numerical value ranges that are to be set can be determined appropriately, and, for example, they may be set to be different from one another according to respective kinds of operation parameters.

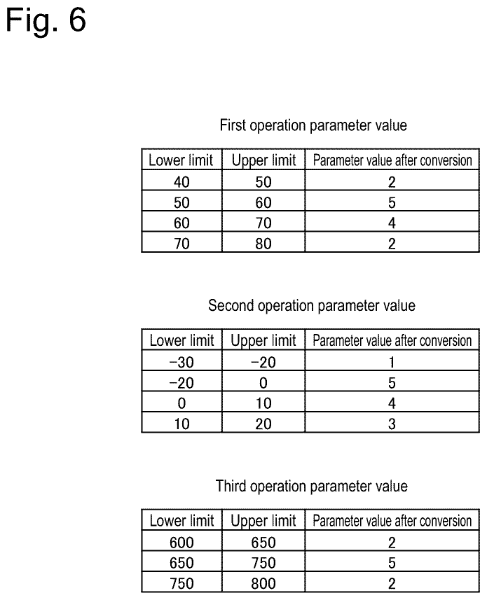

FIG. 6 is a figure used for explaining an example of discretization, and shows tangible examples of discretization with respect to multiple operation parameter values obtained from the spin rinse dryer 50 (the fourth modules 2401-2402). In this example, regarding the first operation parameter value (for example, the above-explained “value of driving current of a motor for rotating a substrate at high speed”) of the spin rinse dryer 50, if the value is that in a range from the lower limit “40” to the upper limit “50,” the value is converted to a value of “2;” if the value is that in a range from the lower limit “50” to the upper limit “60,” the value is converted to a value of “5;” if the value is that in a range from the lower limit “60” to the upper limit “70,” the value is converted to a value of “4;” and, if the value is that in a range from the lower limit “70” to the upper limit “80,” the value is converted to a value of “2.” Further, regarding the second operation parameter value (for example, the above-explained “rotation position of the motor”) of the spin rinse dryer 50, if the value is that in a range from the lower limit “−30” to the upper limit “−20,” the value is converted to a value of “1;” if the value is that in a range from the lower limit “−20” to the upper limit “0,” the value is converted to a value of “5;” if the value is that in a range from the lower limit “0” to the upper limit “10,” the value is converted to a value of “4;” and, if the value is that in a range from the lower limit “10” to the upper limit “20,” the value is converted to a value of “3.” Further, regarding the third operation parameter value (for example, the above-explained “speed of supply of cleaning liquid”) of the spin rinse dryer 50, if the value is that in a range from the lower limit “600” to the upper limit “650,” the value is converted to a value of “2;” if the value is that in a range from the lower limit “650” to the upper limit “750,” the value is converted to a value of “5;” and, if the value is that in a range from the lower limit “750” to the upper limit “800,” the value is converted to a value of “2.”

In this regard, a post-conversion value may represent the state of an operation parameter value, wherein, a larger post-conversion value indicates that an operation parameter has a better value, for example. For example, the post-conversion value of “5” may mean that the operation parameter is that in the best state, and the post-conversion value of “1” may mean that the operation parameter is that in the worst state (for example, an abnormal state).

FIG. 6 is that showing examples of discretization of operation parameter values obtained from one of the fourth modules 2401-2402 (the spin rinse dryers 50) in the plating apparatus 100; and it can be understood that discretization of operation parameter values obtained from other modules in the plating apparatus 100, for example, the first module 2101 (the fixing station 29), the second modules 2201-2202 (the pre-wet tanks 32), the third modules 2301-2310 (the plating tanks 39), and so on, is similar to that explained above.

Next, in step 406, the processor 322 determines the module state of each module, based on multiple operation parameter values of each module obtained in step 402 or based on discretized multiple operation parameter values of each module obtained in step 404. The module state is an index representing whether the module is running normally. Determining of the module state of each module may be based on, for example, the sum of the multiple operation parameter values of the module obtained in step 402 or the sum of the discretized multiple operation parameter values of the module obtained in step 404.

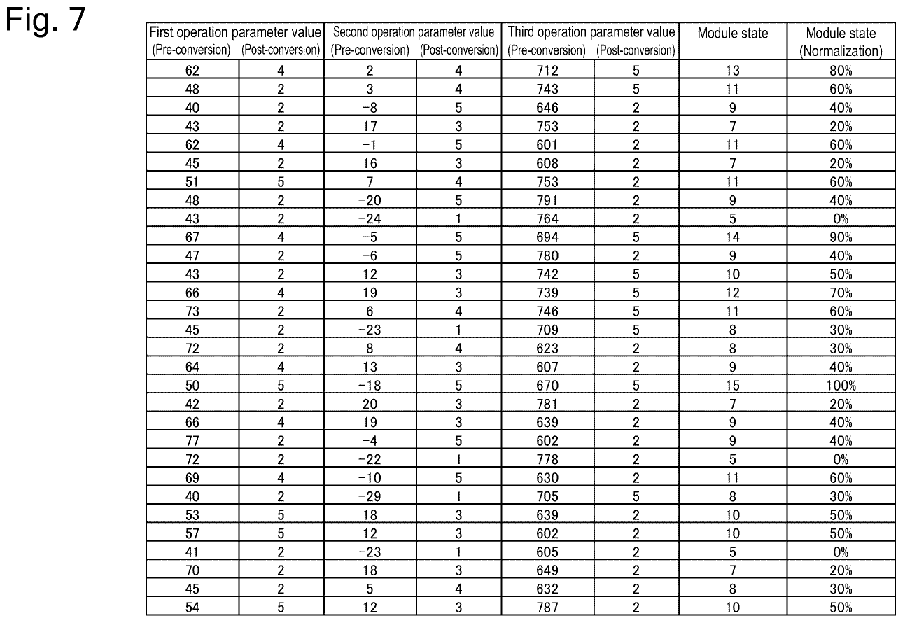

FIG. 7 is a figure which shows calculation examples of module states. This example is that representing calculation examples of module states based on multiple operation parameter values of the spin rinse dryer 50 (the fourth module). Each row in the table in FIG. 7 corresponds to operation parameter values obtained at measurement timing, wherein the measurement timing when operation parameter values in one row are obtained is different from the measurement timing when the operation parameter values in other rows are obtained. For example, when a reference is made to the first row in FIG. 7, it is shown that the first, second, and third operation parameter values obtained from the spin rinse dryer 50 at the above measurement timing are “62,” “2,” and “712,” and these values are converted (according to the tables in FIG. 6) to discretized operation parameter values “4,” “4,” and “5,” respectively. Further, “13” that is the sum of the discretized operation parameter values is determined as the module state of the spin rinse dryer 50 (one of the fourth modules 2401 and 2402) at the above measurement timing. Explanation similar to the above explanation also applies to the data in the second row and the rows following the second row in FIG. 7.

FIG. 7 is that showing examples relating to one of the fourth modules 2401-2402 (the spin rinse dryers 50) in the plating apparatus 100; and it can be understood that explanation similar to the above explanation also applies to the cases of other modules in the plating apparatus 100, for example, the first module 2101 (the fixing station 29), the second modules 2201-2202 (the pre-wet tanks 32), the third modules 2301-2310 (the plating tanks 39), and so on.

In this regard, as shown in the right-most column in the table in FIG. 7, the processor 322 may normalize, by further using a predetermined method, the values of the module states that have been calculated as explained above. For example, normalization may be performed in such a manner that, with respect to multiple module states obtained in relation to the module in a predetermined measurement period, the smallest value is converted to “0” and the largest value is converted to “100.”

Next, in step 408, the processor 322 determines a health index of the plating apparatus 100, based on the module states of the modules obtained in step 406 and the weight coefficients for the modules. The health index is an index obtained by converting, to a numerical form, the degree of normality of operation of the apparatus, and, for example, a higher numerical value may represent a higher degree of normality with respect to the operation state. The plating apparatus 100 (in general, a substrate processing apparatus) comprises multiple module groups, and, in a series of processes performed in the plating apparatus 100, importance of each module group is different from that of other module groups. Accordingly, by assigning, to each module, a weight coefficient corresponding to importance of each module group in the plating apparatus 100, and determining a health index by taking the weight coefficient into consideration, it becomes possible to know the health state of the plating apparatus 100 with high accuracy.

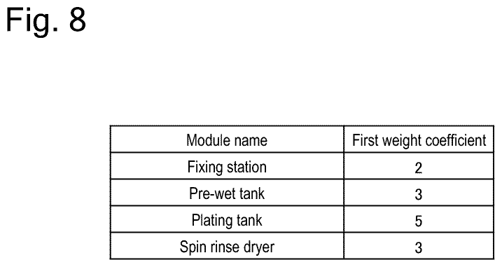

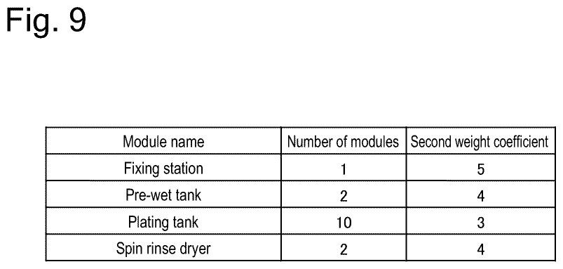

Each of FIG. 8 and FIG. 9 is a figure which shows examples of weight coefficients. FIG. 8 shows examples of first weight coefficients, and FIG. 9 shows examples of second weight coefficients. The first weight coefficient for the first module 2101 (i.e., the fixing station 29) belonging to the first module group 210 is set to “2,” the first weight coefficient for the second modules 2201-2202 (i.e., the pre-wet tanks 32) belonging to the second module group 220 is set to “3,” the first weight coefficient for the third modules 2301-2310 (i.e., the plating tanks 39) belonging to the third module group 230 is set to “5,” and the first weight coefficient for the fourth modules 2401-2402 (i.e., the spin rinse dryers 50) belonging to the fourth module group 240 is set to “3.” The first weight coefficient may be that representing the degree of importance of the functional action of a module group in the series of processes performed in the plating apparatus 100 in such a manner that a higher first weight coefficient value represents a higher degree of importance. For example, the plating step performed in the plating tank 39 is the most important step in the plating apparatus 100, and the most important matter that should be considered in terms of the health index of the plating apparatus 100 is whether each plating tank 39 is running normally; and, accordingly, in the example in FIG. 8, the maximum value “5” is assigned to the first weight coefficient for the third modules 2301-2310 (i.e., the plating tanks 39).

On the other hand, each second weight coefficient is set according to the number of usable modules included in each module group. For example, the second weight coefficient may be set in such a manner that the value thereof becomes larger as the number of usable modules in the module group becomes smaller. This is because, in calculation of a health index, it is desirable to assign larger weight to a module belonging to a module group including a smaller number of usable modules, since importance of a single module in a module group including a smaller number of usable modules is relatively high when it is compared with importance of a single module in a module group including a larger number of usable modules. In the examples in FIG. 9, and when a reference is also made to the example in FIG. 2, the first module group 210 comprises a single first module 2101 (i.e., the fixing station 29), the second module group 220 comprises two second modules 2201-2202 (i.e., the pre-wet tanks 32), the third module group 230 comprises ten third modules 2301-2310 (i.e., the plating tanks 39), and the fourth module group 240 comprises two fourth modules 2401-2402 (i.e., the spin rinse dryers 50). Accordingly, the second weight coefficient for the first module group 210 that includes the smallest number of usable modules (the fixing station 29) is set to the maximum value of “5,” and the second weight coefficient for the third module group 230 that includes the largest number of usable modules (the plating tanks 39) is set to the smallest value of “3.” Further, with respect to each of the second module group 220 (the pre-wet tanks 32) and the fourth module group 240 (the spin rinse dryers 50), the number of modules included therein is that between the largest number and the smallest number, and the second weight coefficient for it is set to a medium value of “4.”

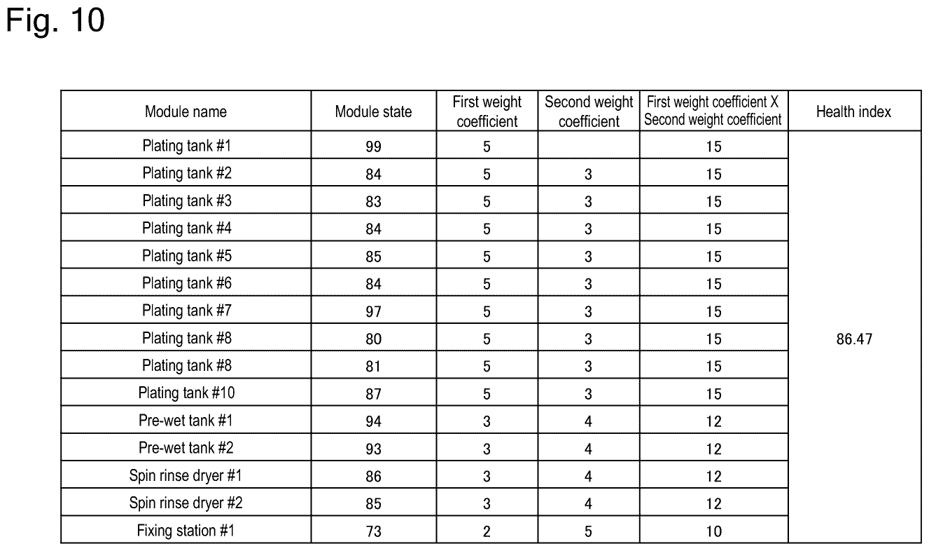

FIG. 10 shows, with respect to each module in the plating apparatus 100, examples of a module state and weight coefficients. In FIG. 10, the module states of the modules are those obtained in step 406, respectively. Further, the first and second weight coefficients shown in FIG. 10 are the same as those in the examples in FIG. 8 and FIG. 9. For example, the processor 322 is able to calculate a health index MHI (Machine Health Index) of the plating apparatus 100 by using a formula shown below. In this regard, in the following formula, it is supposed that MCi is the module state of an i-th module, W1ᵢ is the first weight coefficient for the i-th module, W2ᵢ is the second weight coefficient for the i-th module, and N is the total number of modules included in the plating apparatus 100 (for example, N=15 in the example in FIG. 2), and the summation (Σ) is performed for all modules included in the plating apparatus 100.

$$MHI = \frac{{\sum }_{i = 1}^{N} {MC}_{i} * W {1}_{i} * W {2}_{i}}{{\sum }_{i = 1}^{N} W {1}_{i} * W {2}_{i}} \qquad ( Formula 1 )$$

It should be reminded that the above formula for the health index MHI is an example formula for calculating the health index of the plating apparatus 100, and the formula used in the present invention is not limited to the above formula. For example, the above formula may be modified by omitting the first weight coefficient or the second weight coefficient, and the health index of the plating apparatus 100 may be defined by using the modified formula.

Next, in step 410, the processor 322 controls, based on the module state of each module obtained in step 406, use/nonuse with respect to the module in the plating apparatus 100. For example, as explained above, regarding the discretized operation parameter value obtained in step 404, a larger value indicates that an operation parameter has a better value. Accordingly, it is possible to regard that operation of a module having a high module state value is being performed normally, and that the state of operation of a module having a low module state value has been deteriorated. Accordingly, for example, the processor 322 controls a module having a module state value larger than a predetermined threshold value to stay in a use mode, and a module having a module state value smaller than the predetermined threshold value to enter a nonuse mode. In this regard, the “use mode” may be a mode that allows use of the module, and, on the other hand, the “nonuse mode” may be a mode that prohibits use of the module, or stops operation of the module.

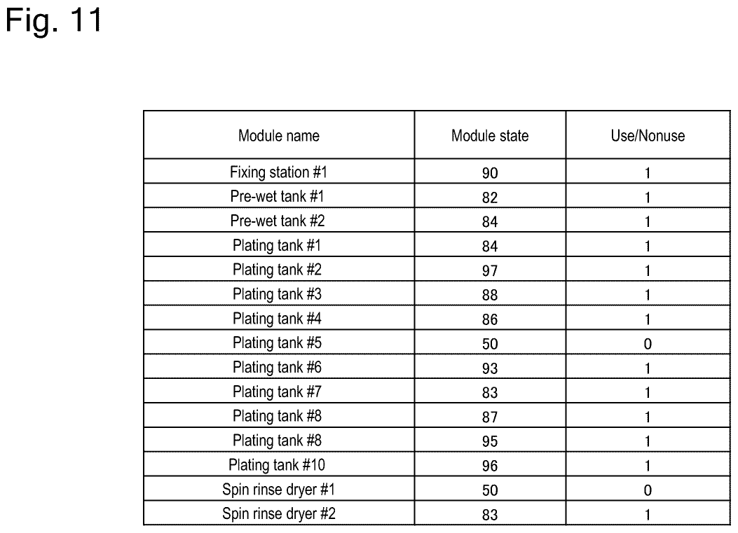

FIG. 11 shows, with respect to each module in the plating apparatus 100, an example of result of judgment in terms of use/nonuse. In this example, the predetermined threshold value is set to “50;” and two modules, specifically, the plating tank #5 and the spin rinse dryer #1, have been controlled to stay in the nonuse modes, and other modules have been controlled to stay in the use modes. It should be noted that, as a result of above control, the number of usable modules in the third module group 230 (the plating tanks 39) has become “9” that is smaller than the number of modules in the case that all (ten) plating tanks 39 are in the use modes, and the number of usable modules in the fourth module group 240 (the spin rinse dryers 50) has become “1” that is smaller than the number of modules in the case that all (two) spin rinse dryers 50 are in the use modes.

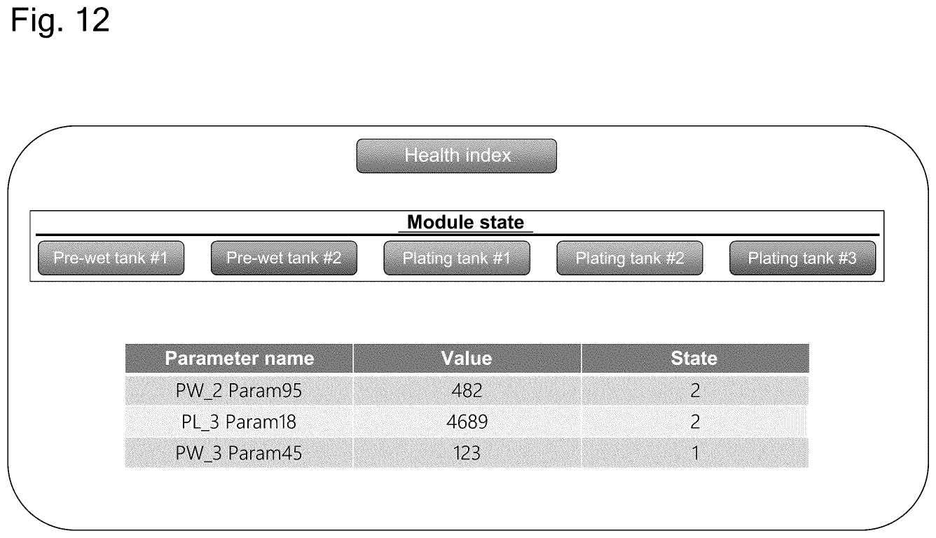

In this regard, for example, in step 410, the processor 322 may display, in a monitor screen of the computer 320, the name(s) of the module(s) which has been controlled to stay in the nonuse mode, and all operation parameter values or abnormal operation parameter values of the module. FIG. 12 shows an example of the monitor screen. By using a monitor screen such as that shown in the figure, a user of the system 300 is allowed to quickly and accurately grasp a module in which a malfunction has occurred and the type of the occurred malfunction.

Next, in step 412, the processor 322 performs judgment as to whether a module(s) with respect to which the mode thereof has been changed, as a result of control in step 410, from the use mode to the nonuse mode or from the nonuse mode to the use mode exists. If there is no such a module, the process returns to step 402, and the above-explained process is repeated.

On the other hand, if there is a module(s) with respect to which the mode thereof has been changed, the process proceeds to step 414, and the processor 322 updates, based on the number of usable modules in each module group in the plating apparatus 100 at present, the above-explained second weight coefficient. Thereafter, the process starting from step 402 is repeated again. For example, when a reference is made to FIG. 9, the number of usable modules in the third module group 230 (the plating tanks 39) is “10,” and the second weigh coefficient corresponding thereto is “3;” however, if the number of usable modules in the third module group 230 is changed to “8” as a result of control in step 410, the processor 322 may change, in step 414, the second weigh coefficient for the third module group from “3” to “4,” for example. By adjusting the second weight coefficient according to the number of actually usable modules in each module group as shown above, it becomes possible to calculate a more precise health index that reflects the state of operation of each module in the plating apparatus 100.

### Second Embodiment

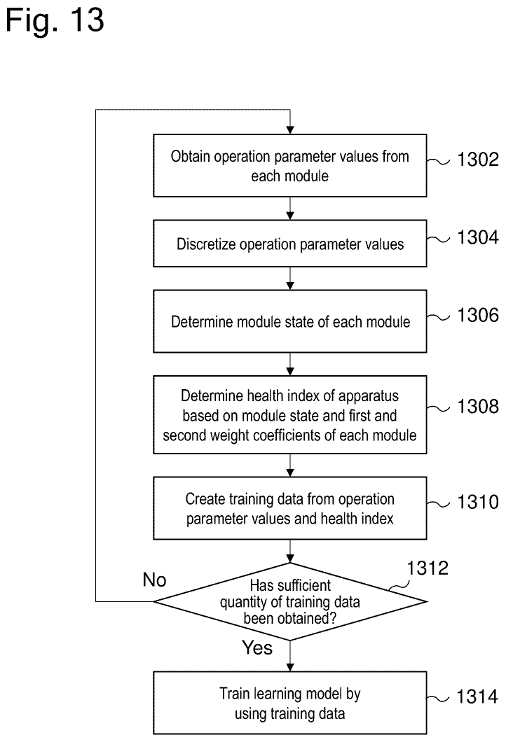

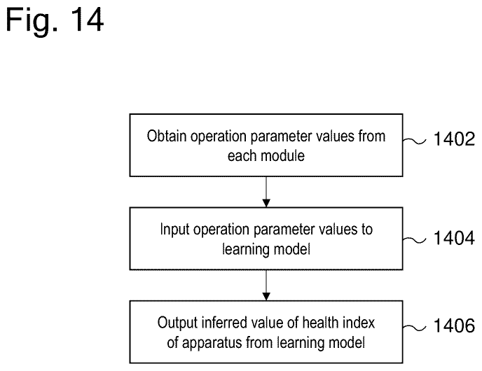

Each of FIG. 13 and FIG. 14 shows a flow chart which shows operation of the system 300 for implementing a method according to a different embodiment of the present invention. The process in each step in the flow charts in FIG. 13 and FIG. 14 is performed by the processor 322 in the computer 320 in the system 300. The method according to the present embodiment infers (determines) the health index of the plating apparatus 100 by using a learning model trained by machine learning. FIG. 13 shows a flow chart relating to a training phase for training a learning model, and FIG. 14 shows a flow chart relating to an operation (inference) phase for inferring the health index by using the trained learning model.

When a reference is made to FIG. 13, the training phase in the present embodiment comprises steps 1302-1310 for creating training data. Steps 1302-1308 in the above steps are those similar to steps 402-408 in the method in the first embodiment explained with reference to FIG. 4. That is, in step 1302, the processor 322 obtains multiple operation parameter values from each module in the plating apparatus 100. In step 1304, the processor 322 performs discretization of the operation parameter values obtained in step 1302 based on predetermined threshold values, respectively. In step 1306, the processor 322 determines the module state of each module, based on the multiple operation parameter values of each module obtained in step 1302 or based on the discretized multiple operation parameter values of each module obtained in step 1304. In step 1308, the processor 322 determines the health index of the plating apparatus 100, based on the module states of the modules obtained in step 1306 and the weight coefficients for the modules. Above steps 1302-1308 may be performed when trial operation of the plating apparatus 100 is performed (for example, by loading a test substrate(s) into the plating apparatus 100 and making respective modules operate); or a certain period in a period, during that a substrate(s) which will becomes an actual finished product(s) is loaded into the plating apparatus 100 and the plating apparatus 100 is operated for actual production, may be defined as a training data creating period, and steps 1302-1308 may be performed in the certain period.

In step 1310 that follows step 1308, the processor 322 forms a set comprising operation parameter values of respective modules in the plating apparatus 100 (for example, all operation parameter values of all modules) obtained in step 1302 and a health index of the plating apparatus 100 calculated based on the operation parameter values in step 1308, and defines the set as a training data set. Thereafter, steps 1302-1310 are repeated (step 1312: No), until a sufficient quantity of training data is obtained. As a result of the above process, training data comprising multiple sets, each set comprising operation parameter values and a health index, is created.

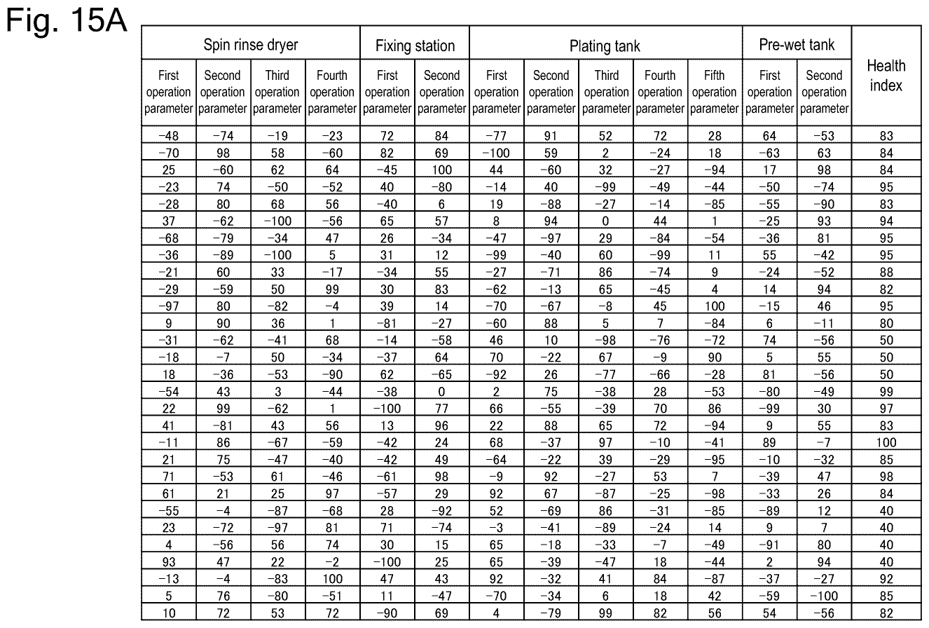

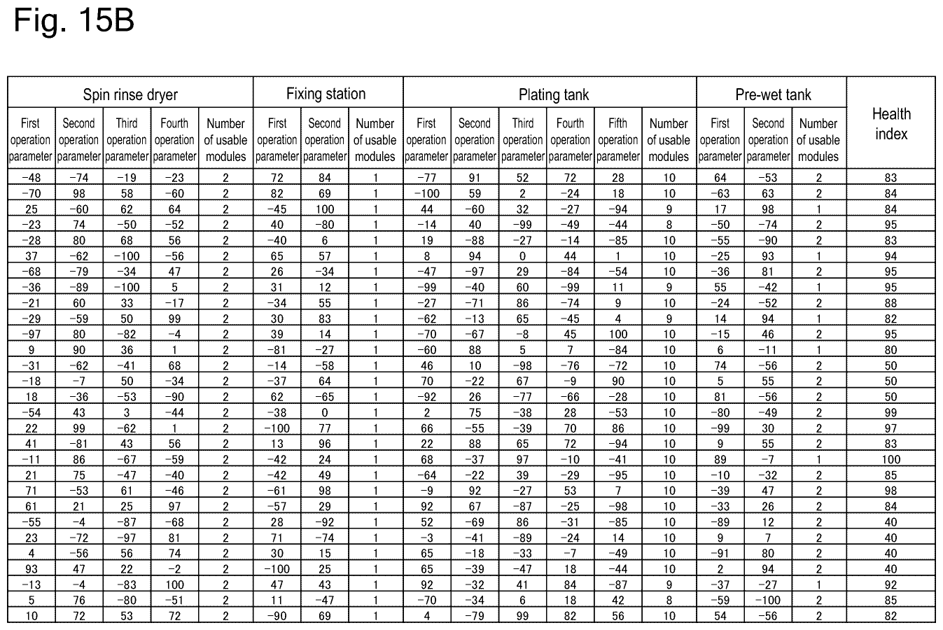

FIG. 15A shows an example of created training data. Each row in a table shown in FIG. 15A shows a training data set obtained by performing steps 1302-1310 a single time. In this regard, as shown in FIG. 15B, the training data may comprise the number of usable modules in each module group.

After a sufficient quantity of training data is obtained by repeating steps 1302-1310 (step 1312: Yes), the processor 322 next trains, in step 1314, the learning model by machine learning using the training data.

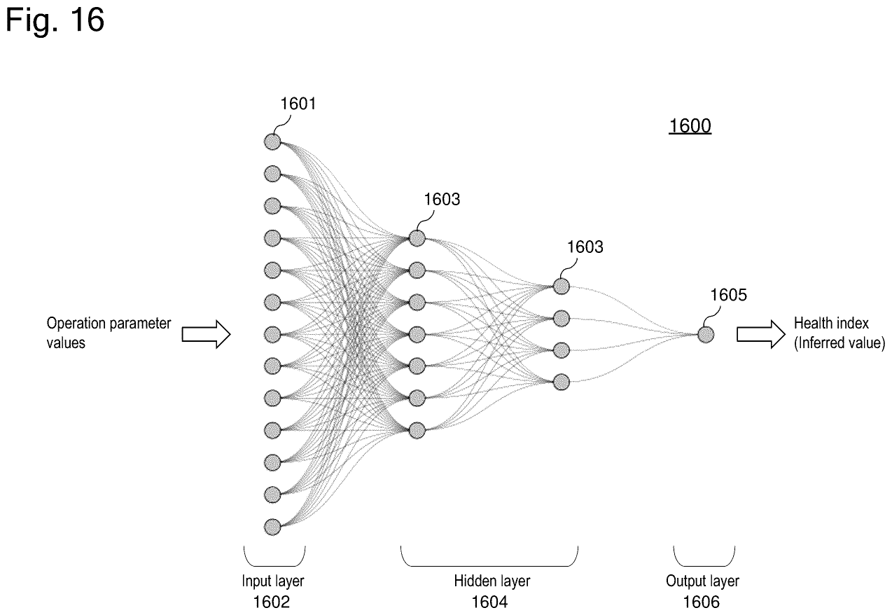

FIG. 16 is a figure which shows a construction of an example learning model which can be used when implementing a method according to the present embodiment. The example learning model 1600 comprises a neural network comprising: an input layer 1602 having multiple input nodes 1601; a hidden layer (an intermediate layer) 1604 comprising a single layer or multiple layers, each having multiple nodes 1603; and an output layer 1606 having a single output node 1605. Each node belonging to one layer is connected, with strength characterized by a weight parameter(s), to multiple nodes of a layer adjacent to the one layer. The operation parameter values of respective modules in the plating apparatus 100 (for example, all operation parameter values of all modules), in the training data, are inputted to the multiple nodes 1603 of the input layer 1602. Further, an inferred value for the health index of the plating apparatus 100 is outputted from the output node 1605 of the output layer 1606. To make the inferred value coincide with the value of the health index in the training data (i.e., by using the value of the health index in the training data as a ground truth label for the inferred value), weight parameters between respective nodes in the neural network 1600 are adjusted, respectively. Adjustment of parameters in the neural network 1600 is repeatedly performed by using multiple training data sets obtained in step 1310 (refer to FIGS. 15A and 15B). In the manner explained above, training of the learning model 1600 is performed.

Next, the operation (inference) phase in the present embodiment will be explained with reference to FIG. 14. During a period when the plating apparatus 100 is being normally operated, the operation (inference) phase shown in FIG. 4 starts from step 1402.

In step 1402, the processor 322 obtains multiple operation parameters from each module in the plating apparatus 100 (for example, from each of the first module 2101, the second modules 2201-2202, the third modules 2301-2310, and the fourth modules 2401-2402 shown in FIG. 2). Step 1402 is the same as step 402 in the method in the first embodiment explained with reference to FIG. 4, and overlapping explanation relating thereto will be omitted.

In step 1404 that follows the above step, the processor 322 inputs, to the input layer 1602 of the learning model 1600 that has been trained in the above-explained training phase, multiple operation parameter values obtained in step 1402 from the respective modules in the plating apparatus 100.

In step 1406, the processor 322 makes the learning model 1600 perform operation and output, from the output layer 1606 (the output node 1605) of the learning model 1600, an inferred value for the health index of the plating apparatus 100. As explained above, according to the method according to the present embodiment, it becomes possible to reduce calculation load required for obtaining the health index of the plating apparatus 100, and obtain an accurate health index, as a result that the learning model trained by machine learning is used.

In the above description, embodiments of the present invention have been explained based on some examples; and, in this regard, the above embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

24 Robot
25 Cassette table
25a Cassette
26 Handling stage
27 Substrate transfer device
29 Fixing station
30 Stocker
32 Pre-wet tank
33 Pre-soak tank
34 Pre-rinse tank
35 Blow tank
36 Rinse tank
37 Transporter
38 Overflow tank
39 Plating tank
50 Spin rinse dryer
50a Washing unit
100 Plating apparatus
110 Load/unload unit
120 Processing unit
120A Pre-processing/post-processing unit
120B Plating processing unit
210 First module group
220 Second module group
230 Third module group
240 Fourth module group
2101 First module
2201-2202 Second module
2301-2310 Third module
2401-2402 Fourth module
300 System
320 Computer
322 Processor
324 Memory
326 Program
330 Network
1600 Learning model
1601 Input node
1602 Input layer
1603 Node
1604 Hidden layer
1605 Output node
1606 Output layer

What is claimed is:

1. A method for determining a health index of a substrate processing apparatus; wherein the substrate processing apparatus comprises multiple module groups, and each module group comprises a single module or multiple modules: and the method comprises steps for
obtaining multiple operation parameter values relating to each of the modules in the substrate processing apparatus;
determining a module state of each of the modules, based on the multiple operation parameter values; and
determining a health index of the substrate processing apparatus, based on the module states of the modules and weight coefficients for the modules.

2. The method as recited in claim 1, wherein the weight coefficient for each of the modules comprises a first weight coefficient that represents a first kind of contribution by the module to the health index and a second weight coefficient that represents a second kind of contribution by the module to the health index.

3. The method as recited in claim 2, wherein
the substrate processing apparatus is constructed to apply, to a substrate, a series of processes by performing characteristic functional actions by the module groups, respectively,
the first weight coefficients are set to values corresponding to the degrees of importance of the functional actions, in the series of processes, performed by the module groups, respectively, and
the second weight coefficients are set to values corresponding to the numbers of useable modules included in the module groups, respectively.

4. The method as recited in claim 3, further comprising steps for:
controlling use or nonuse of each of the modules, based on the module state of the module, and
changing, in the case that a module being used in the modules is made to be unused or a module being unused in the modules is made to be used, the second weight coefficient according to change in the number of usable modules.

5. The method as recited in claim 2, wherein the step for determining the health index comprises calculating, in relation to each module, a product of the module state value, the first weight coefficient, and the second weight coefficient.

6. The method as recited in claim 5, wherein the step for determining the health index comprises calculating the sum of the products relating to all modules, wherein each of the products is that calculated in relation to each of the modules.

7. The method as recited in claim 1, further comprising a step for controlling use or nonuse of each module, based on the module state of the module.

8. The method as recited in claim 7, further comprising
a step for performing discretization of the multiple operation parameter values relating to each module, based on predetermined threshold values, respectively; wherein
the step for determining the module state comprises calculating the sum of the discretized multiple operation parameter values relating to the module, or the sum of the multiple operation parameter values relating to the module.

9. The method as recited in claim 7, further comprising a step for identifying an abnormal operation parameter, with respect to a module which has been controlled to be unused in the modules, based on the multiple operation parameter values or the discretized multiple operation parameters.

10. A method for determining a health index of a substrate processing apparatus; wherein the substrate processing apparatus comprises multiple module groups, and each module group comprises a single module or multiple modules; and the method comprises steps for
obtaining multiple operation parameter values relating to each of the modules in the substrate processing apparatus;
training a learning model by machine learning, for making it output a value relating to a health index of the substrate processing apparatus when the multiple operation parameter values relating to multiple modules in the substrate processing apparatus are inputted thereto; and
inferring, by using the trained learning model and from multiple operation parameter values of the multiple modules at present, a health index of the substrate processing apparatus at present: wherein
the step for training the learning model by machine learning comprises steps for
calculating a module state of each module, by calculating, with respect to the module, the sum of the multiple operation parameter values or discretized values of the multiple operation parameter values;
calculating a health index of the substrate processing apparatus, by calculating the sum of products, each product being a product of a module state of each module and a weight coefficient for the module; and
training the learning model by using, as training data, the multiple operation parameter values relating to the multiple modules in the substrate processing apparatus and the calculated health index.

11. The method as recited in claim 10, wherein the trained learning model is installed in the substrate processing apparatus.

12. A substrate processing apparatus comprising a controller and multiple module groups, each module group comprising a single module or multiple modules, wherein the controller is constructed to
obtain multiple operation parameter values relating to each of the modules in the substrate processing apparatus,
determine a module state of each of the modules, based on the multiple operation parameter values, and
determine a health index of the substrate processing apparatus, based on the module states of the modules and weight coefficients for the modules.

13. A substrate processing apparatus comprising a controller and multiple module groups, each module group comprising a single module or multiple modules, wherein the controller is constructed to
obtain multiple operation parameter values relating to each of the modules in the substrate processing apparatus, and
infer, by using a learning model trained by machine learning for outputting a value relating to a health index of the substrate processing apparatus when the multiple operation parameter values relating to multiple modules in the substrate processing apparatus are inputted thereto, and from multiple operation parameter values of the multiple modules at present, a health index of the substrate processing apparatus at present; wherein
the learning model is that trained by
calculating a module state of each module, by calculating, with respect to the module, the sum of the multiple operation parameter values or discretized values of the multiple operation parameter values,
calculating a health index of the substrate processing apparatus, by calculating the sum of products, each product being a product of a module state of each module and a weight coefficient for the module, and
training the learning model by using, as training data, the multiple operation parameter values relating to the multiple modules in the substrate processing apparatus and the calculated health index.

14. The substrate processing apparatus as recited in claim 13, wherein the trained learning model is installed in the substrate processing apparatus.
